(19) United States
(12) Patent Application Publication
(10) Pub. No.: US 2008/0217631 A1
(43) Pub. Date: Sep. 11, 2008

(54) Semiconductor light emitting apparatus and the manufacturing method thereof

(75) Inventors: Chin-Yuan Hsu, Kaohsiung City (TW); Chia-Hsien Chang, Yongjing Township (TW)

Correspondence Address: Joe McKinney Muncy, PO Box 1364, Fairfax, VA, 22038-1364, US

(73) Assignee: Everlight Electronics Co., Ltd.

(21) Appl. No.: 11/889,952

(22) Filed: Aug. 17, 2007

(30) Foreign Application Priority Data
Mar. 7, 2007 (TW) 96107932

(51) Int. Cl. H01L 33/00; H01L 21/00

(52) U.S. Cl. 257/94; 257/98; 438/27; 257/E33.001

(57) ABSTRACT

A semiconductor light emitting apparatus is provided. The semiconductor light emitting apparatus includes a light-emitting device, a transparent material and at least one transparent film. The light-emitting device is located in a package substrate. The transparent material covers the light-emitting device. The transparent film is located between the light-emitting device and the transparent material. The refractive index of the transparent film is between the refractive index of the light-emitting device and the transparent material. A method for manufacturing the semiconductor light emitting apparatus is also disclosed.

### RELATED APPLICATIONS

This application claims priority to Taiwan Application Serial Number 96107932, filed Mar. 7, 2007, which is herein incorporated by reference.

### BACKGROUND

1. Field of Invention

The present invention relates to a light emitting apparatus and the manufacturing method thereof. More particularly, the present invention relates to a semiconductor light emitting apparatus and the manufacturing method thereof.

2. Description of Related Art

White light-emitting apparatus including a light-emitting diode (LED) is gradually used in various illuminating products and backlight of liquid crystal display, because it is featured by low power consumption, low driving voltage, long lifetime and environmentally friendly characteristics.

In a conventional package process, an epoxy resin or a silicone is filled into the light-emitting apparatus to cover and protect the light-emitting diode inside the light-emitting apparatus. The refractive index of the epoxy resin or the silicone given above is about 1.4˜1.6. The refractive index of the light-emitting diode is about 2.5˜4.0. The large refractive index difference between the epoxy resin (or the silicone) and the light-emitting diode reduces the critical angle inside the light-emitting diode. Therefore, total internal reflection easily occurs in the light-emitting diode, and emission light from the light-emitting diode is further reduced. Therefore, it is necessary to develop a new light-emitting apparatus structure to avoid such problem.

### SUMMARY

A semiconductor light-emitting apparatus is provided. The semiconductor light emitting apparatus includes a light-emitting device, a transparent material and at least one transparent film. The light-emitting device is located in a package substrate. The transparent material covers the light-emitting device. The transparent film is located between the light-emitting device and the transparent material. The refractive index of the transparent film is between the refractive index of the light-emitting device and the transparent material.

A method for manufacturing a semiconductor light emitting apparatus is provided. A light-emitting device having a first refractive index is first formed in a package substrate. Subsequently, at least one transparent film having a second refractive index is formed on a surface of the light-emitting device. Finally, a transparent material having a third refractive index is filled into the package substrate to cover the light-emitting device. The second refractive index given above is between the first refractive index and the third refractive index.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view of a semiconductor light emitting apparatus according to one embodiment of the present invention.

### DETAILED DESCRIPTION

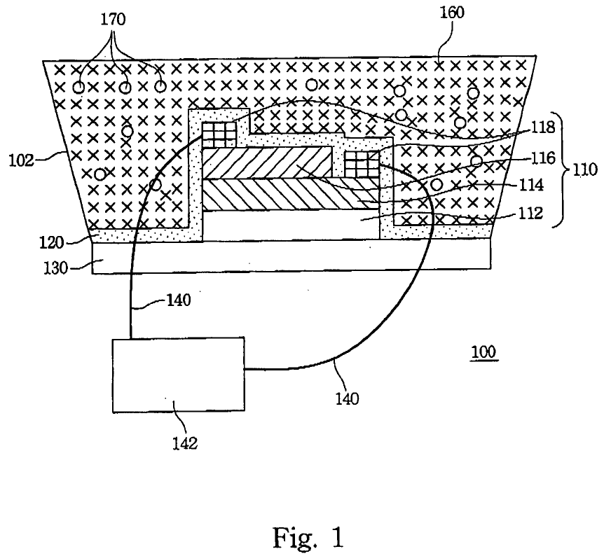

Referring to FIG. 1, a cross-sectional view of a semiconductor light emitting apparatus according to one embodiment of the present invention is shown. The semiconductor light emitting apparatus 100 includes a light-emitting device 110, a transparent material 160 and a transparent film 120. The light-emitting device 110 is located in a package substrate 102 such as package cup or slug. The transparent material 160 is filled into the package substrate 102 and covers the light-emitting device 110. The transparent film 120 is located between the light-emitting device 110 and the transparent material 160. The refractive index of the transparent film 120 is between the refractive index of the light-emitting device 110 and the transparent material 160.

The light-emitting device 110 can include a device substrate 112, a N-type semiconductor device 114, a P-type semiconductor device 116 and plural electrodes 118. The material of the device substrate 112 can be sapphire, silicon, metal, silicon carbide, aluminum nitride or gallium nitride. The material of the N-type semiconductor device 114 and the P-type semiconductor device 116 can be gallium nitride, aluminum gallium nitride, indium gallium nitride, gallium arsenide, gallium phosphide, aluminum gallium arsenide, aluminum gallium indium phosphide, zinc selenide or silicon carbide. The refractive index of the material given above is from 2.5 to 4.0. The location of the N-type semiconductor device 114 and the P-type semiconductor device 116 is exchangeable. The location between of the N-type semiconductor device 114 and the P-type semiconductor device 116 can further include a multiple quantum well (MQW) material layer. The material of the MQW material layer can be GaₓIn₁₋ₓN, AlₓGa₁₋ₓN or (Al_{y}Ga_{1-y})ₓIn₁₋ₓP. The electrodes 118 are located on the surface of the N-type semiconductor device 114 and the P-type semiconductor device 116. The electrodes 118 are electrically connected to a power supply 142 with wire 140. The power supply 142 is used for supplying current for light-emitting device 110. The light-emitting device can be any practicable structure and is not limited to the structure given above.

The transparent material 160 given above can be silicone or a transparent resin such as epoxy resin. The refractive index of the epoxy resin or the silicone is about 1.4˜1.6. The transparent film 120 can be a monolayer/multi-layers structure consisting of diamond film, diamond-like film, aluminum nitride film, boron nitride film or a combination thereof. The refractive index of diamond film is about 2.4. The refractive index of diamond-like film is about 1.7˜2.4. The refractive index of aluminum nitride film and boron nitride film is about 1.8˜2.2. The critical angle inside the light-emitting device 110 can be increased after the transparent film 120 given above is formed on the light-emitting device 110. Therefore, the problem of total internal reflection occurring in the light-emitting device 110 can be improved by increasing the critical angle inside the light-emitting device 110. The amount of light emitting from the light-emitting device 110 can be further increased. Besides, the diamond film, diamond-like film, aluminum nitride film and the boron nitride formed on the light-emitting device 110 and featured by excellent heat conductivity also can improve the heat dissipation of the light-emitting device 110.

The thickness of the transparent film 120 consisting of diamond film and/or diamond-like film is from about 500 angstrom to about 10000 angstrom. The light generated from the light-emitting device is capable of passing through the transparent film 120 consisting of diamond film and/or diamond-like film with such thickness. If the transparent film 120 is formed with the monolayer/multi-layer consisting of aluminum nitride film and/or boron nitride film, the thickness of the transparent film 120 can be about 50˜10000 nm to enable the light generated from the light-emitting device 110 to pass through the transparent film 120.

A method for manufacturing the semiconductor light emitting apparatus 100 given above is disclosed in the specification. The light-emitting device 110 is first formed in the package substrate 102. The transparent film 120 is subsequently formed on the light-emitting device 110. Finally, the transparent material 160 is filled into the package substrate 102 to cover the light-emitting device 110.

The light-emitting device 110 can be formed by any practicable method. For example, the N-type semiconductor device 114 and the P-type semiconductor device 116 of the light-emitting device 110 can be formed on the device substrate 112 by crystallization method. The electrode 118 can be further formed on the surface of the N-type semiconductor device 114 and the P-type semiconductor device 116 by vacuum deposition method or sputtering deposition method.

The transparent film 120 given above can be formed on the light-emitting device 110 by vacuum deposition method, sputtering deposition method or plasma-enhanced chemical vapor deposition method. The transparent material 160 can be formed by coating method, ink-jet method or any practicable method.

Referring to FIG. 1 again, the semiconductor light emitting apparatus 100 can be a white light semiconductor light emitting apparatus including at least one fluorescent material 170 such as phosphor. The fluorescent material 170 is distributed in the transparent material 160. When the fluorescent material 170 (e.g. yellow fluorescent material) is excited by the light generated from the light-emitting device 110 (e.g. blue light), a color light (e.g. yellow light) is emitted from the fluorescent material 170. The color light emitted from the fluorescent material 170 (e.g. yellow light) can further be mixed with the light emitted from the light-emitting device 110 (e.g. blue light) to generate white light.

The semiconductor light emitting apparatus 100 can further include a heat-dissipation device 130 used for reducing the temperature of the light-emitting device 110 when the semiconductor light emitting apparatus 100 is operated. The heat-dissipation device 130 can be a heat sink made of aluminum or copper. The heat sink can be located below the light-emitting device 110 and contacted to the light-emitting device 110 or the transparent film 120. Therefore, the heat generated by the light-emitting device 110 can be dissipated by transferred to the heat sink, and the temperature of the light-emitting device 110 can be reduced. It will further increase the lifetime of the semiconductor light emitting apparatus 100.

Although the present invention has been described in considerable detail with reference to certain embodiments thereof, other embodiments are possible. Therefore, their spirit and scope of the appended claims should no be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor light-emitting apparatus, comprising:
a light-emitting device located in a package substrate;
a transparent material covering the light-emitting device; and
at least one transparent film, located between the light-emitting device and the transparent material, wherein the refractive index of the transparent film is between the refractive index of the light-emitting device and the transparent material.

2. The semiconductor light emitting apparatus of claim 1, wherein the transparent film is selected from a group consisting of a diamond film, a diamond-like film, an aluminum nitride film, a boron nitride film and a combination thereof.

3. The semiconductor light emitting apparatus of claim 2, wherein the thickness of the transparent film consisting of the diamond film and/or the diamond-like film is about 500˜10000 angstrom, to enable the light generated from the light-emitting device to pass through the transparent film.

4. The semiconductor light emitting apparatus of claim 2, wherein the refractive index of the diamond-like film is about 1.7˜2.4.

5. The semiconductor light emitting apparatus of claim 2, wherein the thickness of the transparent film consisting of the aluminum nitride film and/or the boron nitride film is about 50˜10000 nm, to enable the light generated from the light-emitting device to pass through the transparent film.

6. The semiconductor light emitting apparatus of claim 1, wherein the light-emitting device comprises:
a device substrate;
a N-type semiconductor device located on the device substrate;
a P-type semiconductor device located on the N-type semiconductor device; and
a plurality of electrodes, located on the surface of the N-type semiconductor device and the P-type semiconductor device.

7. The semiconductor light emitting apparatus of claim 6, wherein the material of the N-type semiconductor device and the P-type semiconductor device is substantially selected from a group consisting of gallium nitride, aluminum gallium nitride, indium gallium nitride, gallium arsenide, gallium phosphide, aluminum gallium arsenide, aluminum gallium indium phosphide, zinc selenide and silicon carbide.

8. The semiconductor light emitting apparatus of claim 1, wherein the transparent material is epoxy resin or silicone.

9. The semiconductor light emitting apparatus of claim 1, further comprising at least one fluorescent material distributed in the transparent material to form a white light semiconductor light emitting apparatus.

10. The semiconductor light emitting apparatus of claim 1, further comprising a heat-dissipation device used for reducing the temperature of the light-emitting device when the semiconductor light emitting apparatus being operated.

11. A method for manufacturing a semiconductor light emitting apparatus, comprising:
forming a light-emitting device in a package substrate, wherein the light-emitting device has a first refractive index;
forming at least one transparent film on a surface of the light-emitting device, wherein the transparent film has a second refractive index; and
filling a transparent material having a third refractive index into the package substrate to cover the light-emitting device, wherein the second refractive index is between the first refractive index and the third refractive index.

12. The semiconductor light emitting apparatus manufacturing method of claim 11, wherein the transparent film is formed by sputtering deposition method, vacuum deposition method or plasma-enhanced chemical vapor deposition method.
